(19) United States
(12) Patent Application Publication
(10) Pub. No.: US 2013/0043476 A1
(43) Pub. Date: Feb. 21, 2013

(54) THIN FILM TRANSISTOR SUBSTRATE AND DISPLAY DEVICE COMPRISING THE SAME

(71) Applicants: Ho-Tsung SUNG, Chu-Nan (TW); Chih-Lung LIN, Chu-Nan (TW)

(72) Inventors: Ho-Tsung SUNG, Chu-Nan (TW); Chih-Lung LIN, Chu-Nan (TW)

(73) Assignees: CHIMEI INNOLUX CORPORATION, Chu-Nan (TW); INNOCOM TECHNOLOGY (SHENZHEN) CO., LTD., Shenzhen City (CN)

(21) Appl. No.: 13/572,545

(22) Filed: Aug. 10, 2012

(30) Foreign Application Priority Data
Aug. 16, 2011 (TW) 100129160

(51) Int. Cl. H01L 29/786

(52) U.S. Cl. 257/59; 257/57; 257/E29.273

(57) ABSTRACT

The invention provides a thin film transistor substrate and a display device including the same. The thin film transistor substrate includes: a substrate; a gate line, a gate insulating layer and an active layer sequentially formed on the substrate; a source and a drain simultaneously formed on the active layer to from a thin film transistor; an insulation layer formed on the thin film transistor, wherein a via is formed in the insulation layer, and the via is formed on a portion of the drain and a portion of the active layer to expose the portion of the drain and the active layer; and a pixel electrode formed in the via and on the insulation layer, wherein the pixel electrode is electrically connected to the drain through the via.

### CROSS REFERENCE TO RELATED APPLICATIONS

This Application claims priority of Taiwan Patent Application No. 100129160, filed on Aug. 16, 2011, the entirety of which is incorporated by reference herein

### BACKGROUND

1. Field

The disclosed embodiments relate to a substrate, and in particular relates to a thin film transistor substrate and a display device comprising the same.

2. Description of the Related Art

Liquid crystal displays are widely used in personal computers, personal digital assistants (PDA), mobile phones or TVs, because they are light, have low power consumption and no radiation.

The liquid crystal display includes a thin film transistor (TFT) substrate and a color filter (CF) substrate facing each other with a liquid crystal layer interposed therebetween. The mode of the liquid crystal display comprises a twisted nematic (TN) mode or an in-plane switching (IPS) mode according to the different designs of the electrode.

FIG. 1 shows a top-view of a conventional in-plane switching (IPS) mode thin film transistor substrate. The thin film transistor substrate 100 in a single pixel region comprises a gate line (also called a scan line) 102, a common line 104, and a data line 106 vertical to the gate line 102. A thin film transistor 108 is on the gate line 102, and a pixel electrode 110 and a common electrode 112 are disposed in the same substrate (not shown in figure). The pixel electrode 110 and a common electrode 112 are individually formed by a transparent conductive material (the pixel electrode 110 and a common electrode 112 are formed on two different layers, and thus they are not electrically connected to each other), and thus the located region of the pixel electrode 110 and a common electrode 112 are called a visible region 114.

In prior art, in order to reduce the feed-through effect, a drain via 185 of a drain 150 is formed on a region (a transparent region) surrounded by the gate line 102 and the date line 106, and the drain 150 is formed by a non-transparent material, and thus the area of the visible region 114 (the dashed line region) is reduced.

Additionally, if the drain via 185 still occupies a portion of the transparent region when the resolution of the liquid crystal display is increased, the aperture ratio (AR) will be reduced. Therefore, there is a need to develop a thin film transistor substrate to resolve the above problem.

### SUMMARY

The disclosure provides a thin film transistor substrate, comprising: a substrate; a gate line, a gate insulating layer and an active layer sequentially formed on the substrate; a source and a drain simultaneously formed on the active layer to from a thin film transistor; an insulation layer formed on the thin film transistor, wherein a via is formed in the insulation layer, and the via is formed on a portion of the drain and a portion of the active layer to expose the portion of the drain and the active layer; and a pixel electrode formed in the via and on the insulation layer, wherein the pixel electrode is electrically connected to the drain through the via.

The disclosure also provides a thin film transistor substrate, comprising: a substrate; a gate line, a gate insulating layer and an active layer sequentially formed on the substrate; a source and a drain simultaneously formed on the active layer to from a thin film transistor; an insulation layer formed on the thin film transistor, wherein a via is formed in the insulation layer, and the via is totally formed on the gate line to expose the portion of the drain; and a pixel electrode formed in the via and on the insulation layer, wherein the pixel electrode is electrically connected to the drain through the via

The disclosure yet provides a display device, comprising: a thin film transistor substrate of the first embodiment to sixth embodiment of the disclosure; a color filter substrate disposed opposite to the thin film substrate; a liquid crystal layer formed between the thin film substrate and the color filter substrate; and a backlight module formed on a side of the thin film substrate away from the color filter substrate

A detailed description is given in the following embodiments with reference to the accompanying drawings.

### BRIEF DESCRIPTION OF THE DRAWING

For a more complete understanding of the disclosure, and the advantages thereof, reference is now made to the following descriptions taken in conjunction with the accompanying drawings, in which:

FIG. 1 shows a top-view of a conventional in-plane switching (IPS) thin film transistor substrate;

FIG. 2A shows a top view of a thin film transistor substrate in accordance with the first embodiment of the disclosure;

FIG. 2B shows a cross-sectional schematic representation of a thin film transistor substrate in accordance with the first embodiment of the disclosure;

FIGS. 3A-3E individually show cross-sectional schematic representations of various stages of fabricating a thin film transistor substrate in accordance with a first embodiment of the disclosure;

FIG. 4A shows a top view of a thin film transistor substrate in accordance with a second embodiment of the disclosure;

FIG. 4B shows a cross-sectional schematic representation of a thin film transistor substrate in accordance with a second embodiment of the disclosure;

FIG. 5A shows a top view of a thin film transistor substrate in accordance with a third embodiment of the disclosure;

FIG. 5B shows a cross-sectional schematic representation of a thin film transistor substrate in accordance with a third embodiment of the disclosure;

FIG. 6A shows a top view of a thin film transistor substrate in accordance with a fourth embodiment of the disclosure;

FIG. 6B shows a cross-sectional schematic representation of a thin film transistor substrate in accordance with a fourth embodiment of the disclosure;

FIG. 7A shows a top view of a thin film transistor substrate in accordance with a fifth embodiment of the invention;

FIG. 7B shows a cross-sectional schematic representation of a thin film transistor substrate in accordance with a fifth embodiment of the disclosure;

FIG. 8A shows a top view and of a thin film transistor substrate in accordance with a sixth embodiment of the disclosure;

FIG. 8B shows a cross-sectional schematic representation of a thin film transistor substrate in accordance with a sixth embodiment of the disclosure; and

FIG. 9 shows a cross-sectional schematic representation of a display device in accordance with the embodiment of the disclosure.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

The disclosure provides a thin film transistor substrate, a drain via of the thin film transistor substrate partially, and not, occupying the position of a transparent region to increase the area of the visible region and the aperture ratio (AR) in a high-resolution liquid crystal display.

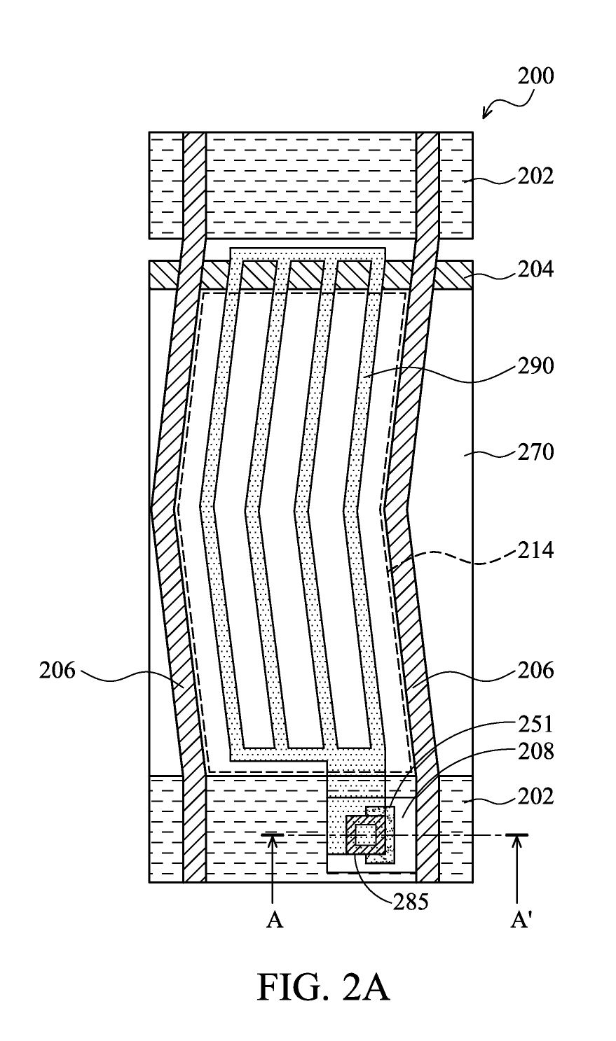

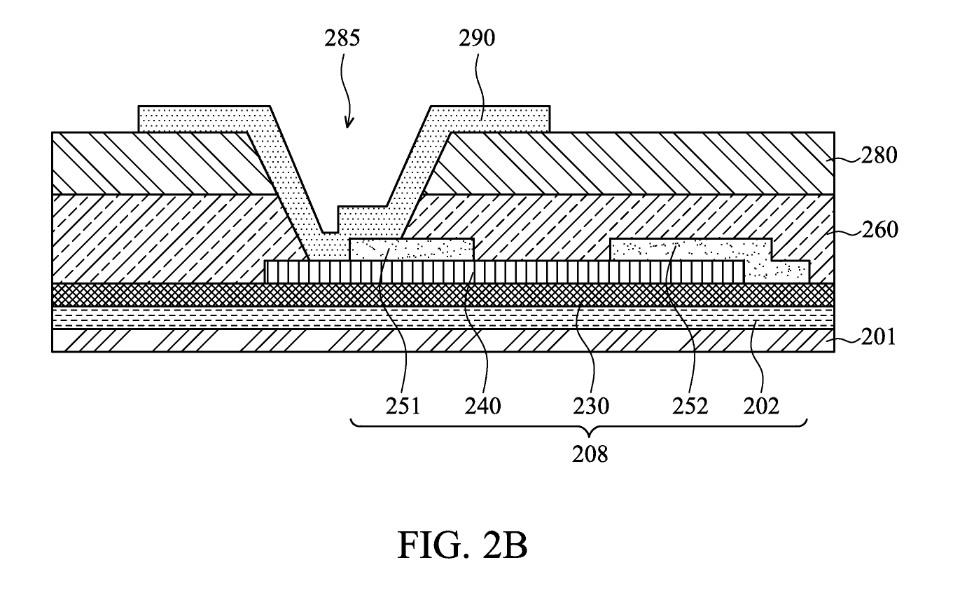

Referring to FIGS. 2A and 2B, FIG. 2A shows a top-view schematic representation of a thin film transistor substrate in accordance with a first embodiment of the disclosure, and FIG. 2B shows a cross-sectional schematic representation along AA′ line of FIG. 2A.

FIG. 2A shows a top-view schematic representation of an in-plane switching (IPS) mode thin film transistor substrate. The thin film transistor substrate in a single pixel comprises a gate line (also called a scan line) 202, a common line 204, and a data line 206 vertical to the gate line 202. A thin film transistor 208 is on the gate line 202, and a pixel electrode 290 and a common electrode 270 are disposed in the same substrate 201 (referring to FIG. 2B).

Referring to FIG. 2B, the gate line 202, a gate insulating layer 230, an active layer 240, a drain 251 and a source 252 are formed to form a thin film transistor 208. The drain 251, the source 252 and the data line 206 are defined by the same metal layer, and a plantation layer 260 and a protective layer 280 are formed on the thin film transistor 208. A drain via 285 is formed in the plantation layer 260 and the protective layer 280. The drain via 285 is formed on a portion of the drain 251 and a portion of the active layer 240 to expose the portion of the drain 251 and the active layer 240. In one embodiment, the active layer 240 is formed by an amorphous silicon (a-Si), and the plantation layer 260 is formed by an organic or inorganic material.

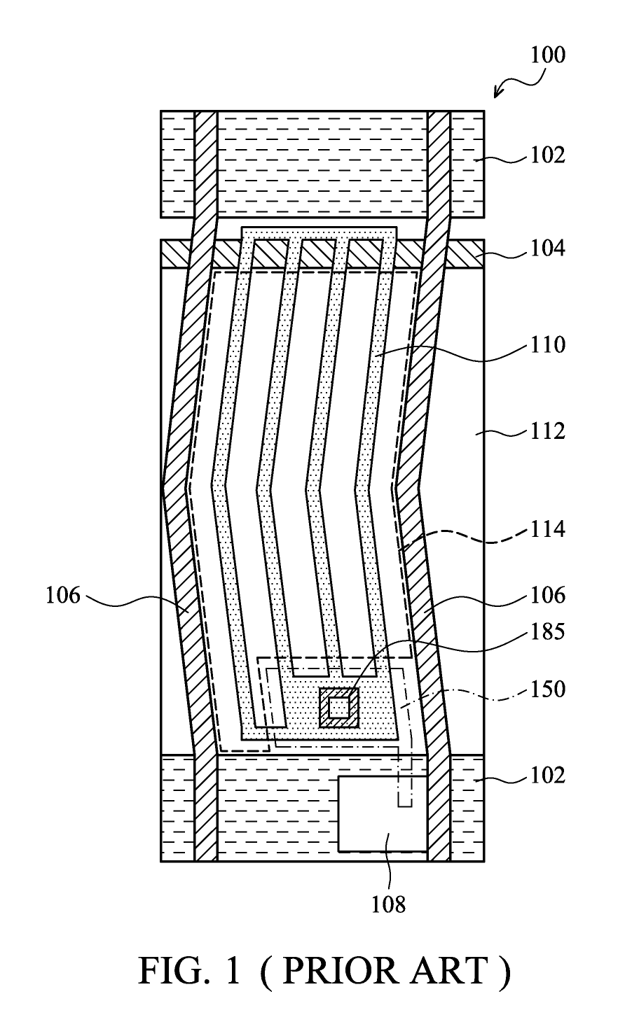

Note that in prior art, the via occupies a portion of the transparent region to reduce the aperture ratio (AR) in the liquid crystal display. In the first embodiment of the disclosure, the drain via 285 is in addition, formed on a portion of the drain 251 and a portion of the active layer 240, and it is also totally formed on the gate line 202. Thus, compared with the prior art, the drain via 285 does not occupy the area of the visible region (the dashed lines in FIG. 1), and the aperture ratio (AR) is improved.

The feed-through effect is represented by the formula (I):

feed through voltage ∝ C_{gd}/Cₛₜ (I)

wherein C_{gd} represents the capacitor between the gate line and the drain, and Cₛₜ represents the storage capacitor.

As shown in formula (I), when the Cₛₜ is increased, the feed through voltage may be decreased. Compared with the twisted nematic (TN) mode, the first embodiment of the disclosure is an in-plane switching (IPS) mode having a larger Cₛₜ, and thus the feed through voltage is smaller. (The capacitor between two plates is represented by C=εA/d, wherein A is an area of the two plates, and d is the distance between two plates. The area of the common electrode 270 in the IPS mode is larger than that in the TN mode, and thus the IPS mode has a larger Cₛₜ.)

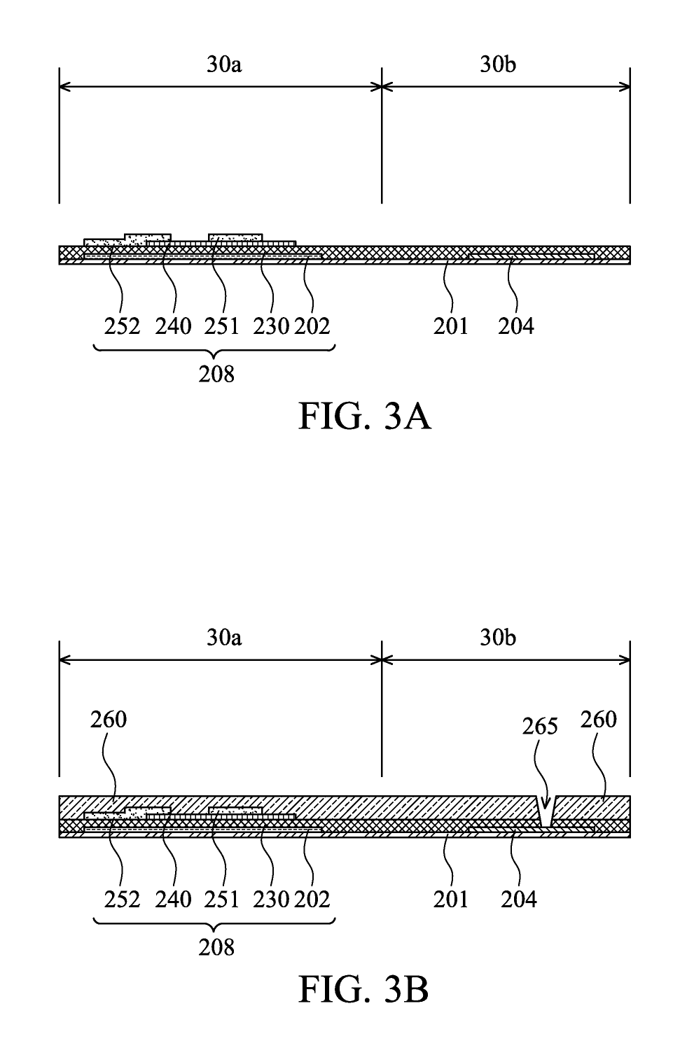

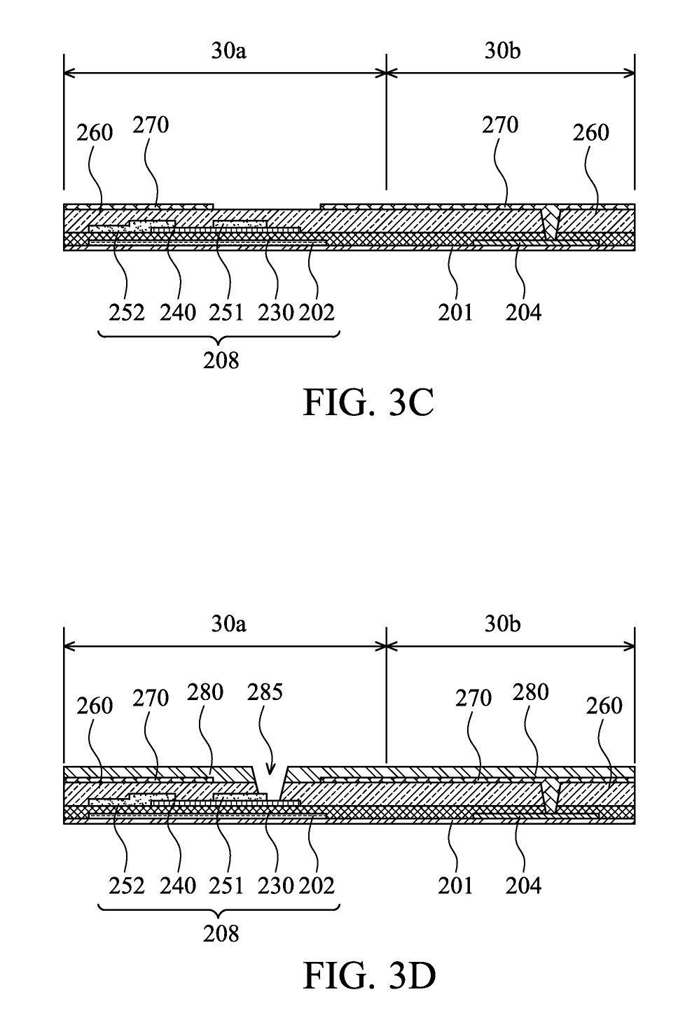

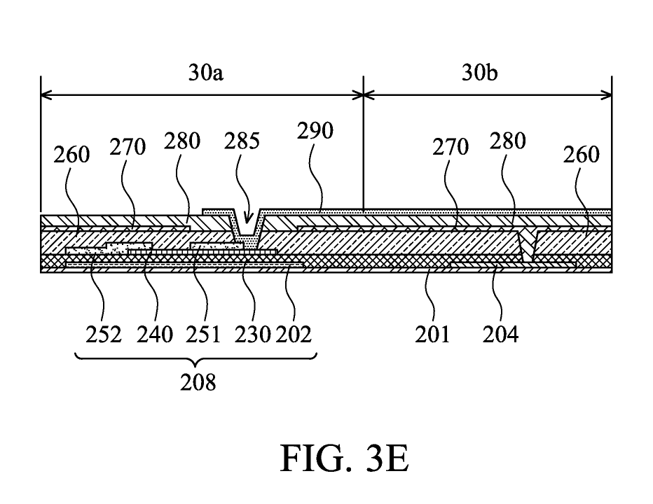

FIGS. 3A-3E show cross-sectional schematic representations of various stages of fabricating a thin film transistor substrate in accordance with the first embodiment of the disclosure, wherein like elements are identified by the same reference numbers as in FIG. 2A-2B, and thus omitted for brevity. Additionally, the photolithography process is known to those skilled in the art, and thus omitted for brevity.

In FIG. 3A, a substrate 201 is firstly provided. The substrate 201 is divided into a thin film transistor region 30a and a storage capacitor region 30b. Then, a metal line is formed on the substrate 201 and patterned to form the gate line 202 in the thin film transistor region 30a and form the common line 204 in the storage capacitor region 30b. The metal line comprises Cu, Al, Mo, Cr, Ti, Ag or combinations thereof. Next, the gate insulating layer 230 is formed on the substrate 201, gate line 202 and the common line 204.

Then, the active layer 240, the drain 251 and the source 252 are in sequence formed on the gate insulating layer 230 in the thin film transistor region 30a. The gate line 202, the gate insulating layer 230, the active layer 240, the drain 251 and the source 252 are formed to form the thin film transistor 208. In one preferable embodiment, the active layer 240 is formed by an amorphous silicon (a-Si).

Referring to FIG. 3B, the plantation layer 260 is formed on the thin film transistor 208 and the gate insulating layer 230. The plantation layer 260 is formed by an insulation material, and preferably an organic material. Then, a first via 265 is formed in the plantation layer 260 and the gate insulating layer 230 in the storage capacitor region 30b to expose the common line 204.

Referring to FIG. 3C, the common electrode 270 is formed in the first via 265, and the common electrode 270 is electrically connected to the common line 204. The common electrode 270 comprises a transparent conductive layer. The transparent conductive layer comprises indium tin oxide (ITO), indium zinc oxide (IZO), cadmium tin oxide (CTO), aluminum zinc oxide (AZO), indium tin zinc oxide (ITZO) zinc oxide, cadmium oxide (CdO), hafnium oxide (HfO), indium gallium zinc oxide (InGaZnO), indium gallium zinc magnesium oxide (InGaZnMgO), indium gallium magnesium oxide (InGaMgO) or indium gallium aluminum oxide (InGaAlO)

Referring to FIG. 3D, the protective layer 280 is formed on the common electrode 270 and the plantation layer 260, and the protective layer 280 is formed by insulation material. Then, the drain via 285 is formed in the protective layer 280 and the plantation layer 260 to expose a portion of the drain 251 and a portion of the active layer 240.

Referring to FIG. 3E, the pixel electrode 290 is formed in the drain via 285 and the protective layer 280, the pixel electrode 290 is electrically connected to the drain 251 and the pixel electrode 290 is formed by a transparent conductive layer. In one preferable embodiment, the common electrode 270 and the pixel electrode 290 are formed by indium tin oxide (ITO).

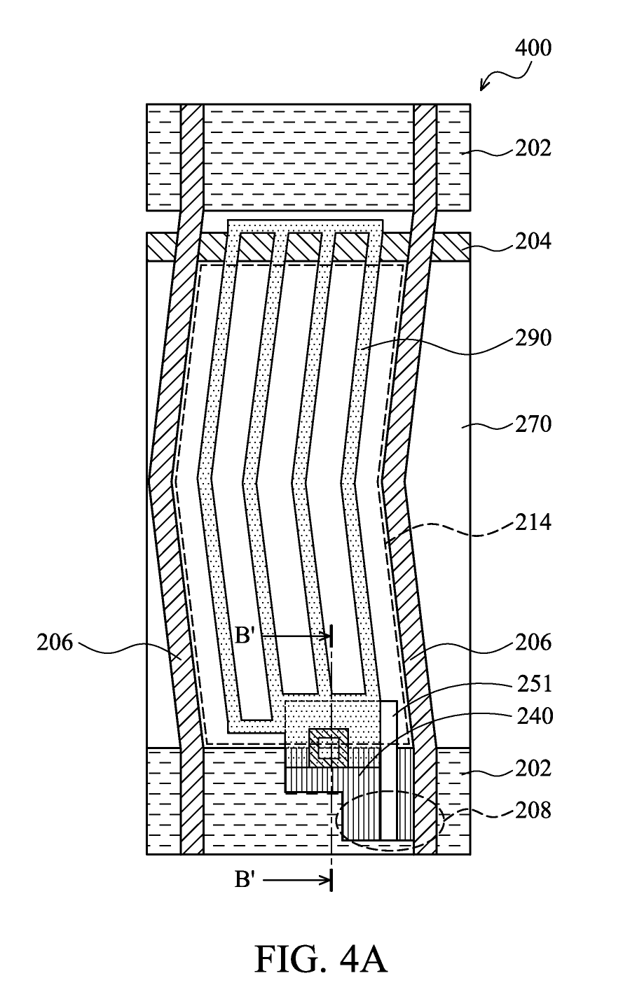

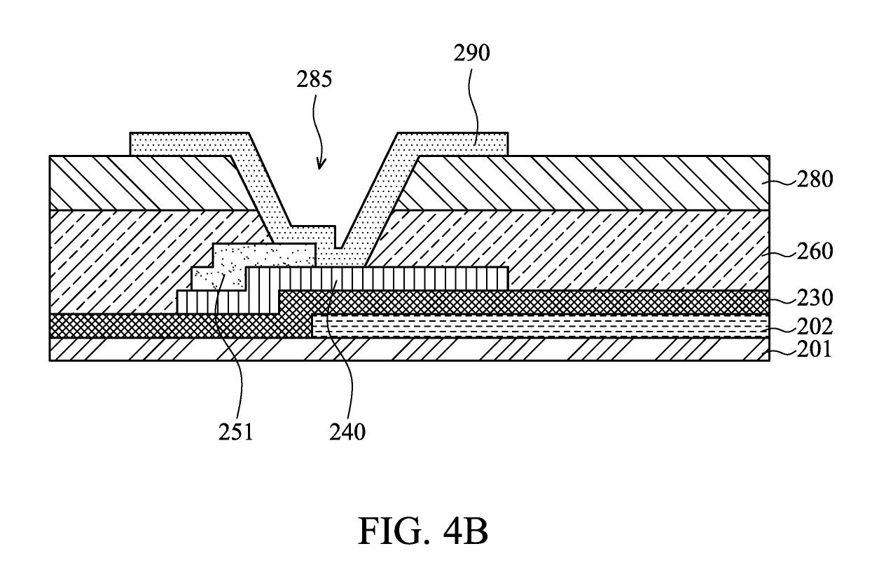

Referring to FIGS. 4A and 4B, FIG. 4A shows a top-view schematic representation of a thin film transistor substrate in accordance with a second embodiment of the disclosure, and FIG. 4B shows a cross-sectional schematic representation along BB′ line of FIG. 4A, wherein like elements are identified by the same reference numbers as in FIG. 2A-2B, and thus omitted for brevity.

Note that the difference between the second embodiment (FIG. 4A) and the first embodiment (FIG. 2A) is that the drain via 285 of the second embodiment is partially formed on the gate line 202, while the drain via 285 of the first embodiment is totally formed on the gate line 202. Compared with the first embodiment, the overlapped region between the gate line 202 and the drain 251 of the second embodiment is smaller, and thus the C_{gd} between the gate line 202 and the drain 251 is smaller. As shown in formula (I), the feed through voltage may be decreased when the C_{gd} is decreased.

The second embodiment relates to an in-plane switching (IPS) mode thin film transistor substrate. The fabrication method of the second embodiment is the same as that of the first embodiment, and thus omitted for brevity.

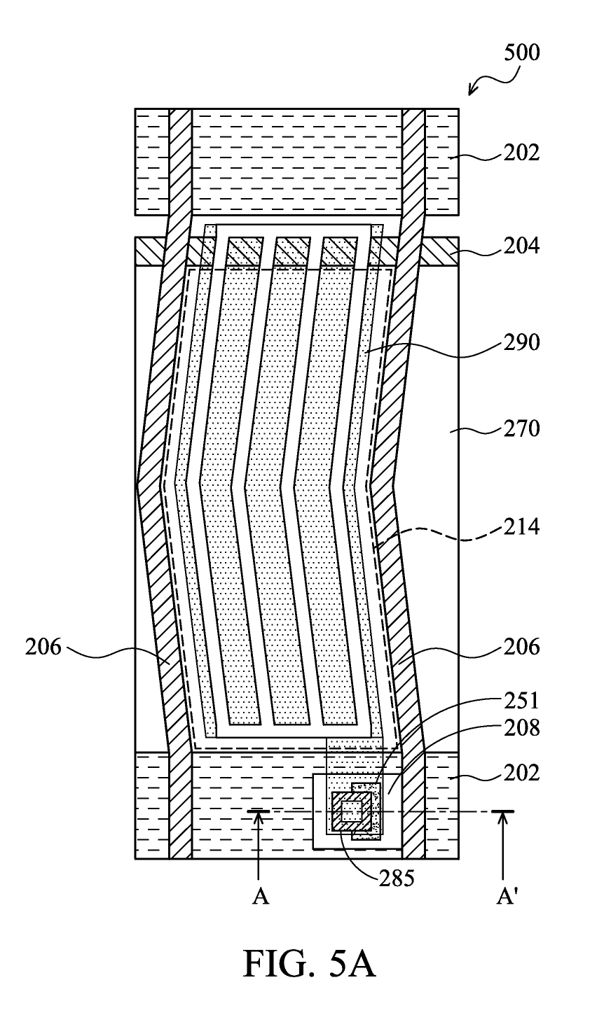

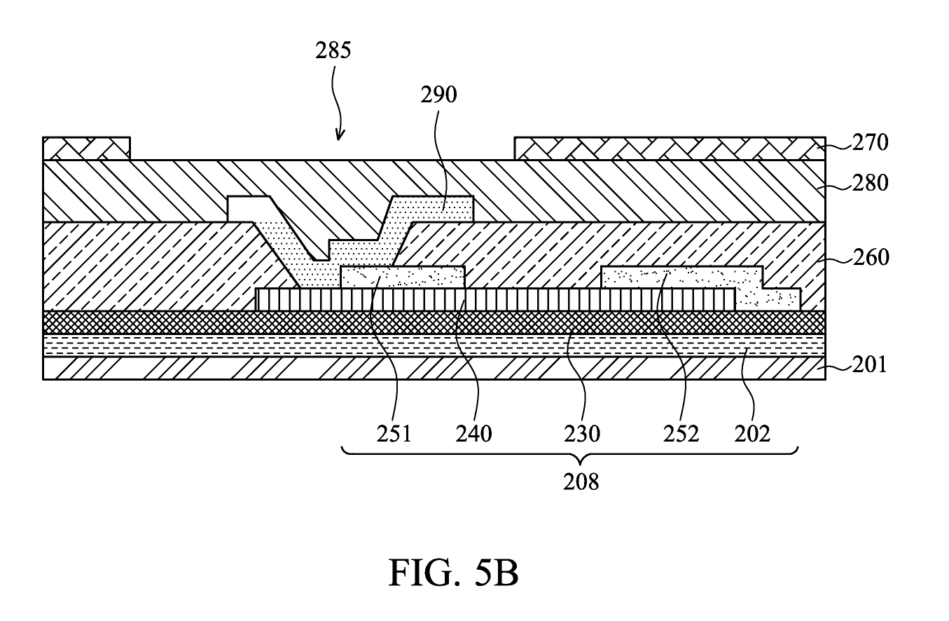

Referring to FIGS. 5A and 5B, FIG. 5A shows a top-view schematic representation of a thin film transistor substrate in accordance with a third embodiment of the disclosure, and FIG. 5B shows a cross-sectional schematic representation along AA′ line of FIG. 5A, wherein like elements are identified by the same reference numbers as in FIG. 2A-2B, and thus omitted for brevity.

In the third embodiment, the drain via 285 is formed on a portion of the drain 251 and a portion of the active layer 240 (referring to FIG. 5A), and totally formed on the gate line 202 (referring to FIG. 5B).

The fabrication method of the third embodiment (see FIG. 5B) is similar to that of the first embodiment (see FIG. 2B) and the only difference therebetween is that in the third embodiment, the electrical connection between the pixel electrode 290 and the drain 251 are firstly formed, and the common electrode 270 are then formed on the protective layer 280.

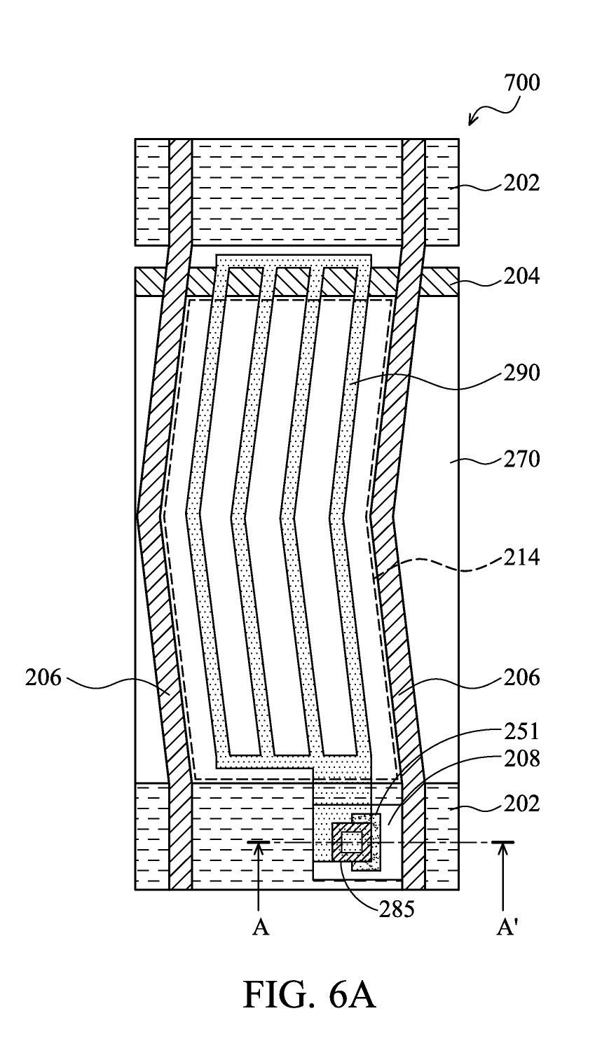

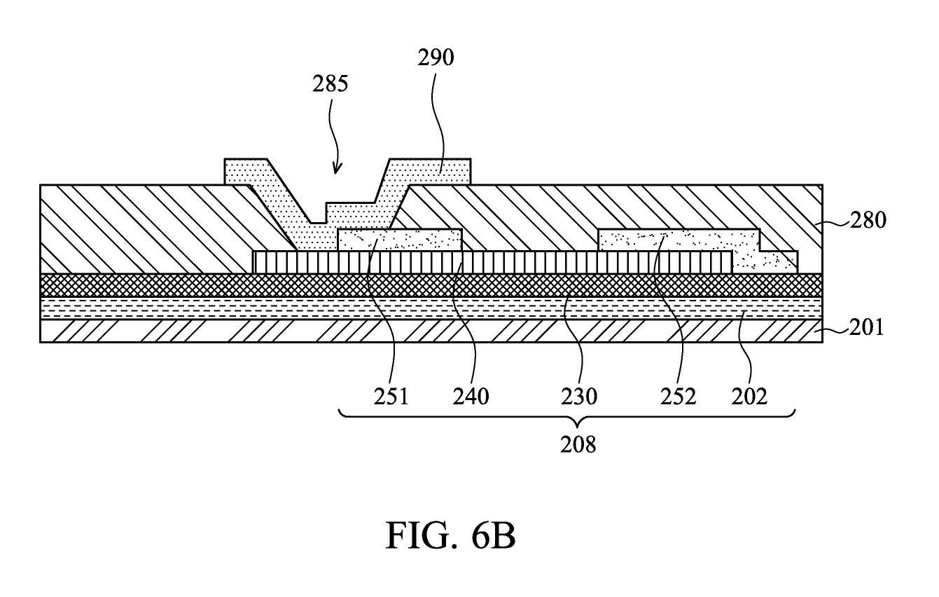

Referring to FIGS. 6A and 6B, FIG. 6A shows a top-view schematic representation of a thin film transistor substrate in accordance with a fourth embodiment of the disclosure, and FIG. 6B shows a cross-sectional schematic representation along AA′ line of FIG. 6A, wherein like elements are identified by the same reference numbers as in FIG. 2A-2B, and thus omitted for brevity.

In the fourth embodiment, the drain via 285 is formed on a portion of the drain 251 and a portion of the active layer 240, and totally formed on the gate line 202. Note that the fourth embodiment has the protective layer 280 but without any plantation layer 260.

In the fourth embodiment, the common line 204 is directly formed on the common electrode 270 (not shown in figure), and thus compared with the first embodiment, there is no need to form the plantation layer and to form the first via in the plantation layer. Therefore, the fabrication steps of the fourth embodiment reduce costs.

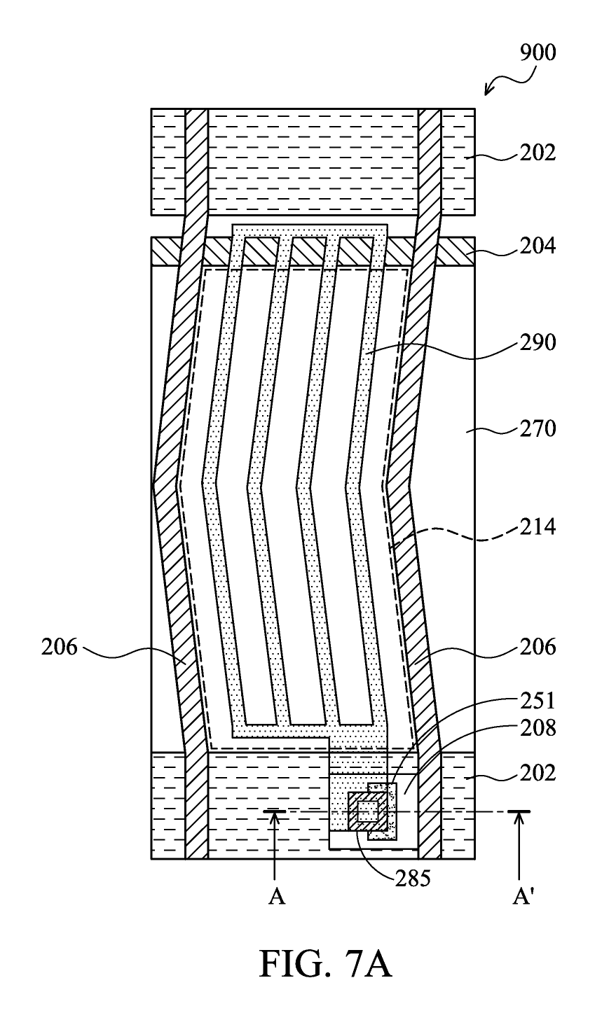

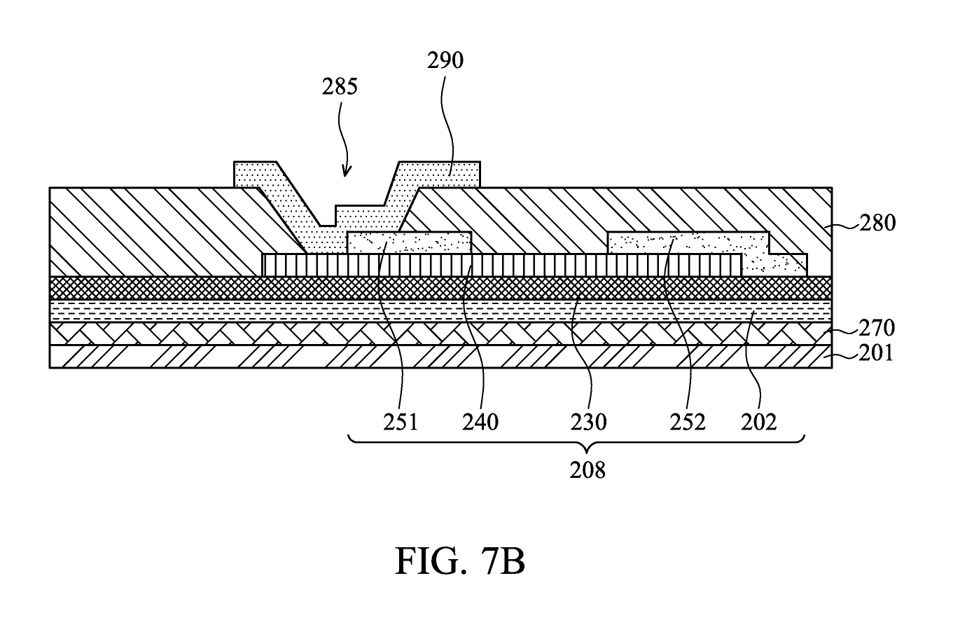

Referring to FIGS. 7A and 7B, FIG. 7A shows a top-view schematic representation of a thin film transistor substrate in accordance with a fifth embodiment of the disclosure, and FIG. 7B shows a cross-sectional schematic representation along AA′ line of FIG. 7A, wherein like elements are identified by the same reference numbers as in FIG. 2A-2B, and thus omitted for brevity.

In the fifth embodiment, the drain via 285 is formed on a portion of the drain 251 and a portion of the active layer 240, and totally formed on the gate line 202. Note that the difference between the first embodiment and the fifth embodiment is that in the fifth embodiment, there is a common electrode 270 formed between the gate line 202 and the substrate 201. In the fifth embodiment, the common electrode 270 and gate line 202 may be formed by a half-tone mask (not shown in figure).

The half-tone mask is composed of a transparent substrate, a metal layer and a semi-transparent film, the semi-transparent film is formed on the transparent substrate, and the metal layer is formed on the semi-transparent film. Because the transmission of the semi-transparent film is different from that of the metal layer, a patterned transparent conductive layer and a patterned metal are simultaneously formed by the half-tone mask. In other words, the original two mask steps are replaced by the one half-tone mask, and thus the fabrication time and cost are reduced.

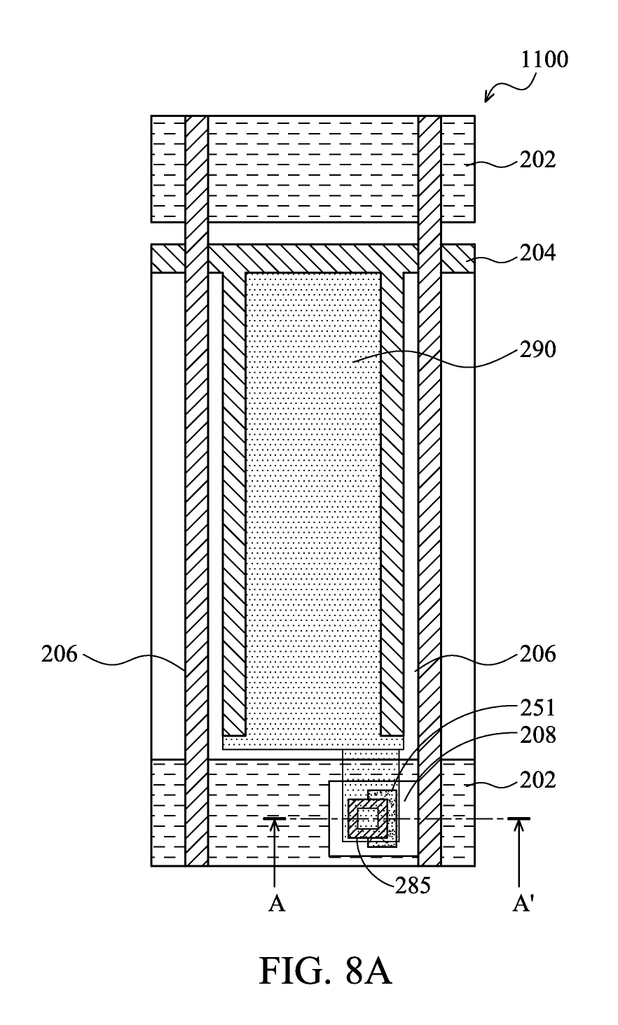

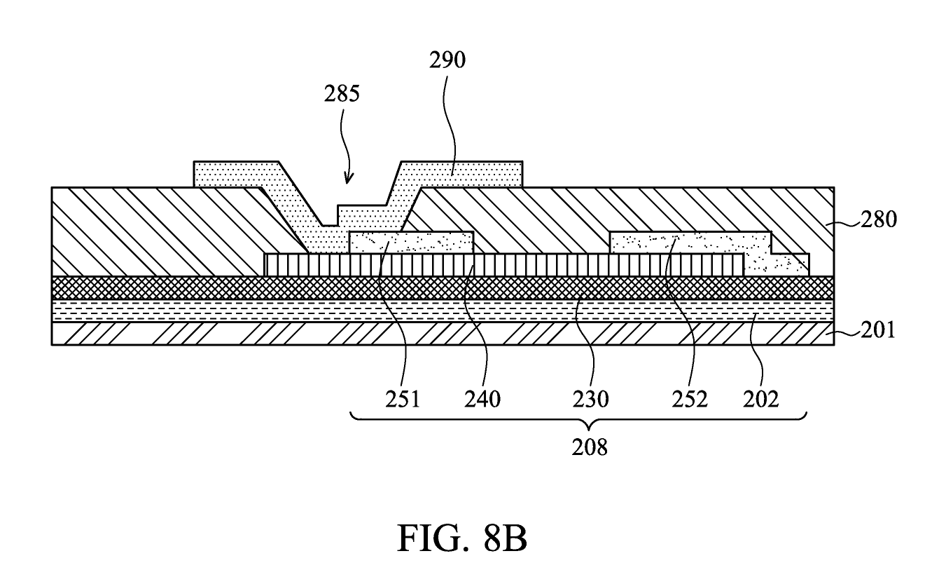

Referring to FIGS. 8A and 8B, FIG. 8A shows a top-view schematic representation of a thin film transistor substrate in accordance with a sixth embodiment of the disclosure, and FIG. 8B shows a cross-sectional schematic representation along AA′ line of FIG. 8A, wherein like elements are identified by the same reference numbers as in FIG. 2A-2B, and thus omitted for brevity.

In the sixth embodiment, the drain via 285 is formed on a portion of the drain 251 and a portion of the active layer 240, and totally formed on the gate line 202. Note that the difference between the first embodiment and the sixth embodiment (see FIG. 8B) is that the sixth embodiment is a twisted nematic (TN) mode.

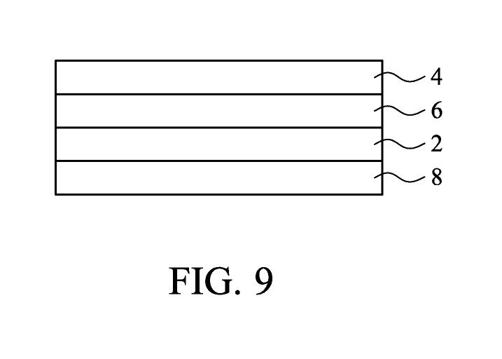

Referring to FIG. 9, the invention also provides a display device comprising: a thin film transistor substrate 2 and a color filter substrate 4 disposed opposite to the thin film substrate 2, wherein the thin film transistor substrate 2 is the first embodiment to the sixth embodiment of the invention; a liquid crystal layer 6 formed between the thin film transistor substrate 2 and the color filter substrate 4; and a backlight module 8 formed on a side of the thin film transistor substrate 2 away from the color filter substrate to provide a light.

The disclosure provides six embodiments, and the first embodiment to the fifth embodiment relate to the in-plane switching (IPS) mode, and the sixth embodiment relates to the twisted nematic (TN) mode. Note that the drain via 285 is formed on a portion of the drain 251 and a portion of the active layer 240, and totally or partially formed on the gate line 202. The aperture ratio (AR) is increased without increasing the feed through voltage by the novel design of the drain via 285 of the invention.

While the invention has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A thin film transistor substrate, comprising:
a substrate;
a gate line, a gate insulating layer and an active layer sequentially formed on the substrate;
a source and a drain simultaneously formed on the active layer to from a thin film transistor;
an insulation layer formed on the thin film transistor, wherein a via is formed in the insulation layer, and the via is formed on a portion of the drain and a portion of the active layer to expose the portion of the drain and the active layer; and
a pixel electrode formed in the via and on the insulation layer, wherein the pixel electrode is electrically connected to the drain through the via.

2. The thin film transistor substrate as claimed in claim 1, wherein the via is partially formed on the gate line.

3. The thin film transistor substrate as claimed in claim 1, wherein the via is totally formed on the gate line.

4. The thin film transistor substrate as claimed in claim 1, wherein the pixel electrode comprises a transparent conductive layer.

5. The thin film transistor substrate as claimed in claim 4, wherein the transparent conductive layer comprises indium tin oxide (ITO), indium zinc oxide (IZO), cadmium tin oxide (CTO), aluminum zinc oxide (AZO), indium tin zinc oxide (ITZO) zinc oxide, cadmium oxide (CdO), hafnium oxide (HfO), indium gallium zinc oxide (InGaZnO), indium gallium zinc magnesium oxide (InGaZnMgO), indium gallium magnesium oxide (InGaMgO) or indium gallium aluminum oxide (InGaAlO).

6. The thin film transistor substrate as claimed in claim 1, wherein the insulation layer comprises a plantation layer, a protective layer or combinations thereof.

7. The thin film transistor substrate as claimed in claim 6, wherein the plantation layer is formed by an organic material.

8. The thin film transistor substrate as claimed in claim 1, wherein the active layer is formed by an amorphous material.

9. A thin film transistor substrate, comprising:
a substrate;
a gate line, a gate insulating layer and an active layer sequentially formed on the substrate;
a source and a drain simultaneously formed on the active layer to from a thin film transistor;
an insulation layer formed on the thin film transistor, wherein a via is formed in the insulation layer, and the via is totally formed on the gate line to expose the portion of the drain; and
a pixel electrode formed in the via and on the insulation layer, wherein the pixel electrode is electrically connected to the drain through the via.

10. The thin film transistor substrate as claimed in claim 9, wherein the via is formed on a portion of the drain and a portion of the active layer to expose the portion of the drain and the active layer.

11. The thin film transistor substrate as claimed in claim 9, wherein the insulation layer comprises a plantation layer, a protective layer or combinations thereof.

12. The thin film transistor substrate as claimed in claim 11, wherein the plantation layer is formed by an organic material.

13. A display device, comprising:
a thin film transistor substrate as claimed in claim 1;
a color filter substrate disposed opposite to the thin film substrate;
a liquid crystal layer formed between the thin film substrate and the color filter substrate; and
a backlight module formed on a side of the thin film substrate away from the color filter substrate.

14. A display device, comprising:
a thin film transistor substrate as claimed in claim 9;
a color filter substrate disposed opposite to the thin film substrate;
a liquid crystal layer formed between the thin film substrate and the color filter substrate; and
a backlight module formed on a side of the thin film substrate away from the color filter substrate.
